(19) United States
(12) Patent Application Publication
(10) Pub. No.: US 2009/0181499 A1
(43) Pub. Date: Jul. 16, 2009

(54) IC PACKAGING PROCESS

(75) Inventor: Chung-Mao YEH, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: Lingsen Precision Industries, Ltd., Taichung (TW)

(21) Appl. No.: 12/033,508

(22) Filed: Feb. 19, 2008

(30) Foreign Application Priority Data
Jan. 16, 2008 (TW) 97101706

(51) Int. Cl. H01L 21/00

(52) U.S. Cl. 438/118; 257/E21.001

(57) ABSTRACT

An IC packaging process includes the steps of forming a photo-curing adhesive layer on a bottom side of a lead frame and then harden the photo-curing adhesive layer; mounting a chip fixedly on a top side of the lead frame and electrically connecting the chip to the lead frame; proceeding to wire bonding to let a plurality of soldering wires electrically connected with the chip and the lead frame; proceeding to molding to let a packaging material package the chip, the soldering wires, and the top side of the lead frame; and removing the photo-curing adhesive layer from the bottom side of the lead frame. In light of the steps, the photo-curing adhesive layer securely shields the bottom side of the lead frame and prevents the packaging material from inleakage into the bottom side of the lead frame to securely avoid the adhesive overflow.

### BACKGROUND OF THE INVENTION

1. Field of the Invention

The present invention relates generally to semiconductor, and more particularly, to an IC packaging process preventing the bottom side of the lead frame in the molding step from adhesive overflow.

2. Description of the Related Art

The conventional IC packaging process generally includes the following steps to prevent the bottom side of the lead frame in the molding step from adhesive overflow. First, an adhesive tape is adhered to the bottom side of the lead frame beforehand. In the step of the molding, the adhesive tape can protect the bottom side of the lead frame from contacting the packaging material. In light of this, the adhesive tape prevents the packaging material from inleakage into the bottom side of the lead frame that is covered by the adhesive tape, thus avoiding the adhesive overflow.

However, the aforesaid adhesive tape is extensible, so the adhesive tape in the molding step is squeezed by the packaging material to be unglued from the bottom side of the lead frame. In other words, the aforesaid adhesive tape fails to securely prevent the packaging material from inleakage into the bottom side of the lead frame and the adhesive overflow still likely happens.

### SUMMARY OF THE INVENTION

The primary objective of the present invention is to provide an IC packaging process, which securely shields the bottom side of the lead frame and prevents it from adhesive overflow.

The foregoing objective of the present invention is attained by the IC packaging process, which includes the following steps:
A. Form a photo-curing adhesive layer on a bottom side of a lead frame and then harden the photo-curing adhesive layer.
B. Mount a chip fixedly on a top side of the lead frame and let the chip electrically connected with the lead frame.
C. Proceed to wire bonding to let a plurality of soldering wires electrically connected with the chip and the lead frame.
D. Proceed to molding to let a packaging material package the chip, the soldering wires, and the top side of the lead frame.
E. Remove the photo-curing adhesive layer from the bottom side of the lead frame.

In light of the above steps, the photo-curing adhesive layer securely shields the bottom side of the lead frame and prevents the packaging material from inleakage into the bottom side of the lead frame, thus securely avoiding the adhesive overflow.

### BRIEF DESCRIPTION OF THE DRAWINGS

FIG. 1 is a flow chart of the present invention.

FIG. 2 is a sectional view of step A1 of a first preferred embodiment of the present invention.

FIG. 3 is a sectional view of step A2 of the first preferred embodiment of the present invention.

FIG. 4 is a sectional view of step A3 of the first preferred embodiment of the present invention.

FIG. 5 is a sectional view of step A4 of the first preferred embodiment of the present invention.

FIG. 6 is a sectional view of step B of the first preferred embodiment of the present invention.

FIG. 7 is a sectional view of step C of the first preferred embodiment of the present invention.

FIG. 8 is a sectional view of step D of the first preferred embodiment of the present invention.

FIG. 9 is a sectional view of step E of the first preferred embodiment of the present invention.

FIG. 10 is a sectional view of a second preferred embodiment of the present invention, showing the structure of the jig.

FIG. 11 is a sectional view of the second preferred embodiment of the present invention, illustrating that the lead frame is stopped against the jig.

FIG. 12 is a sectional view of the second preferred embodiment of the present invention, illustrating that the photo-curing adhesive is infused into the receiving space of the jig to contact the bottom side of the lead frame.

### DETAILED DESCRIPTION OF PREFERRED EMBODIMENTS

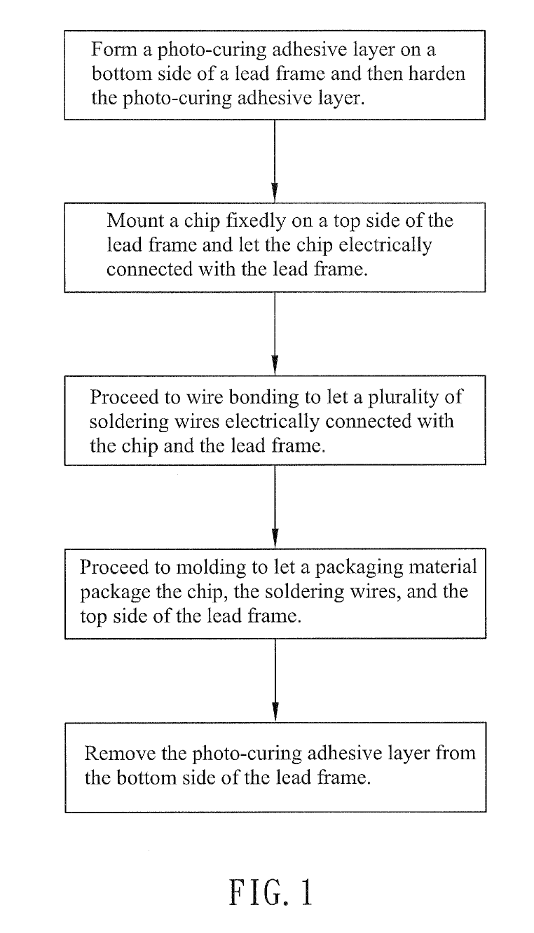

Referring to FIGS. 1-9, an IC packaging process of a first preferred embodiment of the present invention includes the following steps.

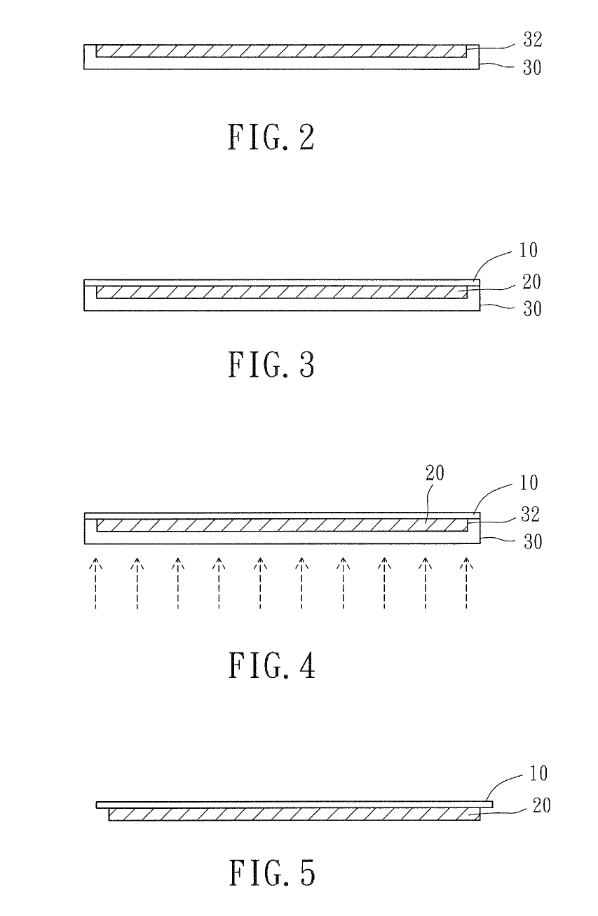

A. Form a photo-curing adhesive layer 20 on a bottom side of a lead frame 10, and then harden the photo-curing adhesive layer 20. This step is composed of the following sub-steps.
A1. Provide a light-permeable jig 30 which is provided with an opening receiving space 32 full of photo-curing adhesive, as shown in FIG. 2.
A2. Let a bottom side of the lead frame 10 be stopped against the jig 30 to contact the photo-curing adhesive and then let the bottom side of the lead frame 10 be equably tainted with the photo-curing adhesive. Accordingly, the photo-curing adhesive layer 20 is formed on the bottom side of the lead frame 10, as shown in FIG. 3.
A3. Irradiate the photo-curing adhesive layer 20 to harden and adhesively attach it to the bottom side of the lead frame 10, as shown in FIG. 4.
A4. Remove the jig 30, as shown in FIG. 5.

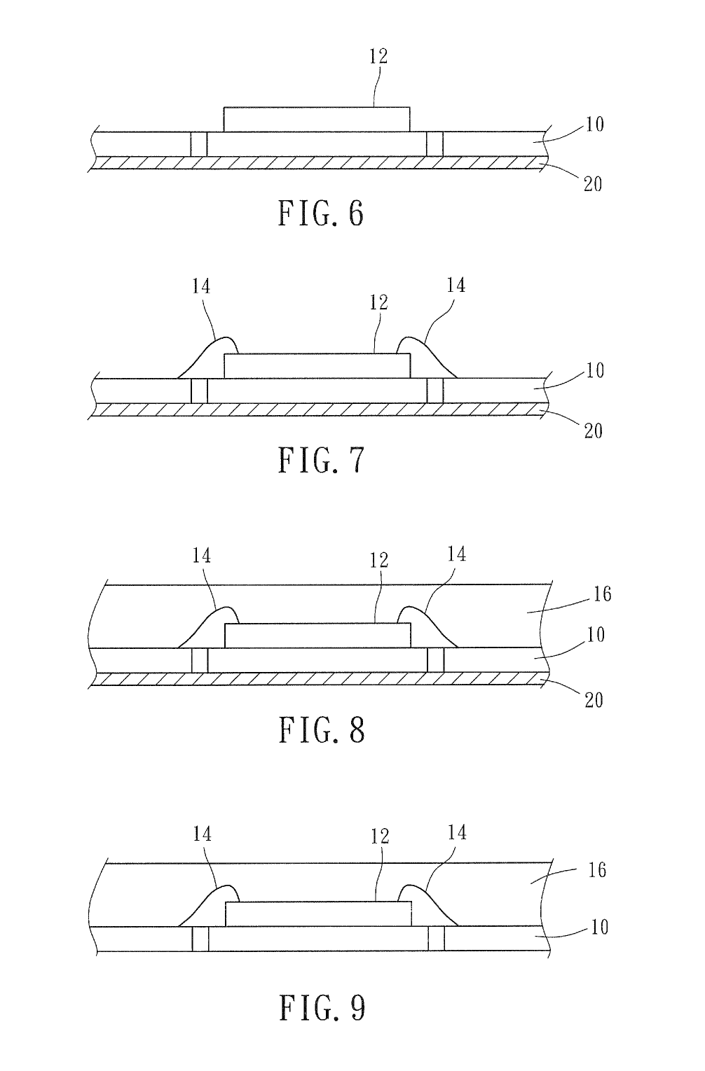

B. Coat silver paste on a top side of the lead frame and then electrically connect a chip 12 fixedly on the top side of the lead frame 10, as shown in FIG. 6.

C. Proceed to wire bonding to let a plurality of soldering wires electrically connected with the chip 12 and the lead frame 10, as shown in FIG. 7.

D. Proceed to molding to let a packaging material 16 to package the chip 12, the soldering wires 14, and the top side of the lead frame 10, as shown in FIG. 8.

E. Remove the photo-curing adhesive layer 20 from the bottom side of the lead frame 10, as shown in FIG. 9, by a method selected from a group consisting of etching, mechanical polishing, and chemical mechanical polishing. In this embodiment, the photo-curing adhesive layer 20 is removed by etching.

In the above steps, the photo-curing adhesive layer 20 provides greater rigidity and adhesive force than the prior art does. In the step of the molding, even if the photo-curing adhesive layer 20 is squeezed by the packaging material 16, it will not be unglued from the bottom side of the lead frame 10. In other words, the photo-curing adhesive layer can securely shield the bottom side of the lead frame 10 and prevent the packaging material 16 from inleakage into the bottom side of the lead frame 10 to avoid adhesive overflow.

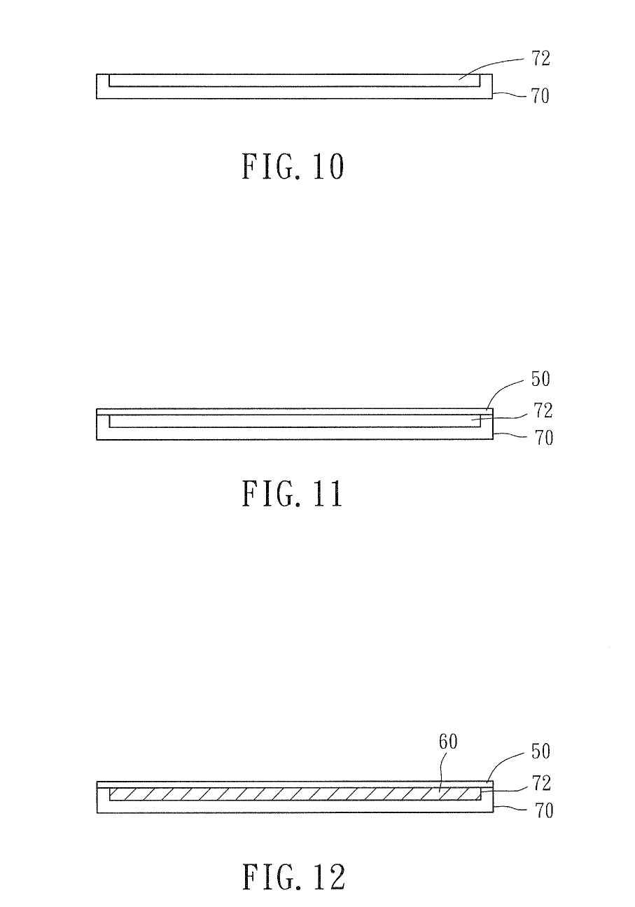

Referring to FIGS. 10-12, an IC packaging process of a second preferred embodiment of the present invention includes the steps similar to those of the first embodiment. The second embodiment is different from the first embodiment only in the following sub-steps of step A: Form a photo-curing adhesive layer 60 on a bottom side of a lead frame 50, and then harden the photo-curing adhesive layer 60.

A1. Provide a light permeable jig 70 having an open receiving space 72, as shown in FIG. 10.

A2. Infuse the photo-curing adhesive into the receiving space 72 until the bottom side of the lead frame 50 contacts the photo-curing adhesive 50, when the bottom side of the lead frame 50 is stopped against the jig 70, as shown in FIG. 11, and let the bottom side of the lead frame 50 to be equably tainted with the photo-curing adhesive 50. Accordingly, the photo-curing adhesive layer 60 is formed on the bottom side of the lead frame 50, as shown in FIG. 12.

A3. Irradiate the photo-curing adhesive layer 60 to harden and adhesively attach it to the bottom side of the lead frame 50.

A4. Remove the jig 70.

Since the other steps B-E of the second embodiment are identical to those of the first embodiment, no more recitation of them is necessary.

Although the present invention has been described with respect to specific preferred embodiments thereof, it is no way limited to the details of the illustrated structures but changes and modifications may be made within the scope of the appended claims.

What is claimed is:

1. An IC packaging process comprising steps of:
(A) forming a photo-curing adhesive layer on a bottom side of a lead frame and then hardening said photo-curing adhesive layer;
(B) electrically connect a chip to a top side of said lead frame;
(C) proceeding to wire bonding to let a plurality of soldering wires electrically connected with said chip and said lead frame;
(D) proceeding to molding to let a packaging material packaging said chip, said soldering wires, and the top side of said lead frame; and
(E) removing said photo-curing adhesive layer from the bottom side of said lead frame.

2. The IC packaging process as defined in claim 1, wherein said step (A) includes the following sub-steps:
(A1) providing a light permeable jig having an open receiving space full of said photo-curing adhesive layer;
(A2) forming said photo-curing adhesive layer on the bottom side of said lead frame when the bottom side of said lead frame is stopped against said jig to contact said photo-curing adhesive layer;
(A3) irradiating said photo-curing adhesive layer to harden and attach said photo-curing adhesive layer to the bottom side of said lead frame; and
(A4) removing said jig.

3. The IC packaging process as defined in claim 1, wherein said step (A) includes the following sub-steps:
(A1) providing a light permeable jig having an open receiving space;
(A2) infusing said photo-curing adhesive layer into said receiving space until the bottom side of said lead frame contacts said photo-curing adhesive layer, when the bottom side of said lead frame is stopped against said jig, whereby said photo-curing adhesive layer is formed on the bottom side of said lead frame;
(A3) irradiating said photo-curing adhesive layer to harden and attach said photo-curing adhesive layer to the bottom side of said lead frame; and
(A4) removing said jig.

4. The IC packaging process as defined in claim 1, wherein said photo-curing adhesive layer is removed by a method selected form a group consisting of etching, mechanical polishing, and chemical mechanical polishing.
